(19) United States
(12) Patent Application Publication
(10) Pub. No.: US 2015/0243512 A1
(43) Pub. Date: Aug. 27, 2015

(54) METHOD OF MANUFACTURING SEMICONDUCTOR DEVICE

(71) Applicant: Kabushiki Kaisha Toshiba, Minato-ku (JP)

(72) Inventors: Kazuki KISHI, Yokkaichi-shi (JP); Tadashi Iguchi, Yokkaichi-shi (JP); Nozomi Kido, Yokkaichi-shi (JP)

(73) Assignee: Kabushiki Kaisha Toshiba, Minato-ku (JP)

(21) Appl. No.: 14/291,209

(22) Filed: May 30, 2014

Related U.S. Application Data
(60) Provisional application No. 61/944,329, filed on Feb. 25, 2014.

(51) Int. Cl. H01L 21/308; H01L 21/02

(52) U.S. Cl. CPC H01L 21/3086; H01L 21/3081; H01L 21/02271

(57) ABSTRACT

In one embodiment, a method of manufacturing a semiconductor device includes forming a first mask layer on a workpiece layer. The method further includes forming a concave portion in the workpiece layer by first etching using the first mask layer. The method further includes forming a second mask layer on the workpiece layer in which the concave portion is formed. The method further includes processing the concave portion of the workpiece layer by second etching using the second mask layer.

### CROSS REFERENCE TO RELATED APPLICATION

This application is based upon and claims the benefit of priority from the prior U.S. Provisional Patent Application No. 61/944,329 filed on Feb. 25, 2014, the entire contents of which are incorporated herein by reference.

### FIELD

Embodiments described herein relate to a method of manufacturing a semiconductor device.

### BACKGROUND

A hard mask is often used for forming a concave portion such as a hole or trench in a workpiece layer having a large thickness. In this case, if a thickness of the hard mask is too small, the hard mask may be entirely removed before the concave portion of the workpiece layer is completed by etching using the hard mask. On the other hand, if the thickness of the hard mask is too large, a resist mask may be entirely removed before a process on the hard mask is completed by etching using the resist mask. Accordingly, there is a problem that it is difficult to form the concave portion in the workpiece layer having a large thickness. Examples of the workpiece layer having a large thickness are a stack film for a three dimensional stack memory and the like.

### BRIEF DESCRIPTION OF THE DRAWINGS

FIGS. 1A to 4B are cross-sectional views showing a method of manufacturing a semiconductor device of a first embodiment;

FIG. 5 is a cross-sectional view showing an example of a stack film of the semiconductor device of the first embodiment; and

FIG. 6 is a cross-sectional view illustrating details of the method of manufacturing the semiconductor device of the first embodiment.

### DETAILED DESCRIPTION

Embodiments will now be explained with reference to the accompanying drawings.

In one embodiment, a method of manufacturing a semiconductor device includes forming a first mask layer on a workpiece layer. The method further includes forming a concave portion in the workpiece layer by first etching using the first mask layer. The method further includes forming a second mask layer on the workpiece layer in which the concave portion is formed. The method further includes processing the concave portion of the workpiece layer by second etching using the second mask layer.

### First Embodiment

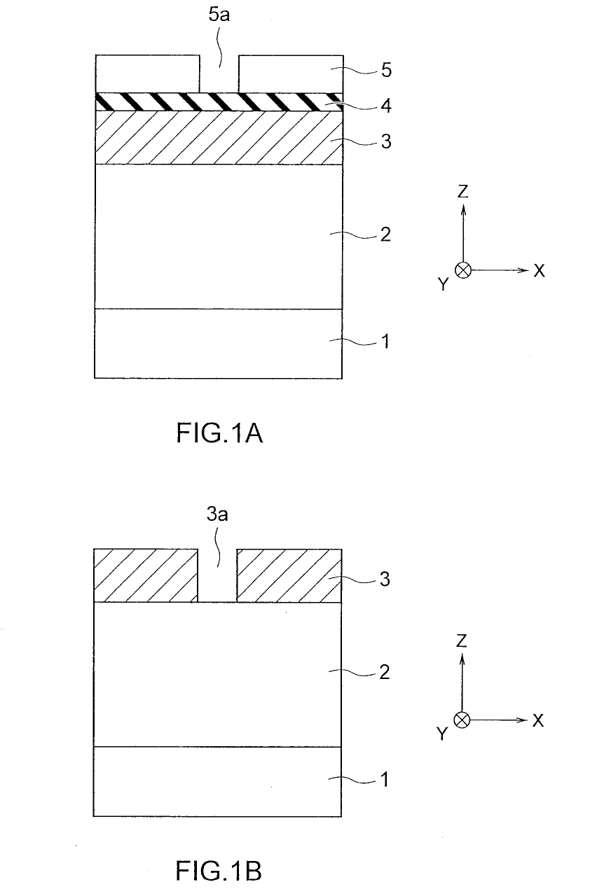

FIGS. 1A to 4B are cross-sectional views showing a method of manufacturing a semiconductor device of a first embodiment. The semiconductor device of the present embodiment is a three dimensional stack memory.

[FIG. 1A]

As shown in FIG. 1A, a stack film 2, a first hard mask layer 3, a cover layer 4 and a resist film 5 are formed on a substrate 1 in this order. The stack film 2 is an example of a workpiece layer. The first hard mask layer 3 is an example of the first mask layer. As shown in FIG. 1A, a concave portion 5a which penetrates the resist film 5 is then formed by patterning the resist film 5.

An example of the substrate 1 includes a semiconductor substrate such as a silicon substrate. FIG. 1A shows X and Y directions which are parallel to a surface of the substrate 1 and are perpendicular to each other, and a Z direction perpendicular to the surface of the substrate 1. In this specification, the +Z direction is represented as an upward direction, and the −Z direction is represented as a downward direction. For example, a positional relationship between the substrate 1 and the stack film 2 is expressed such that the substrate 1 is positioned under the stack film 2.

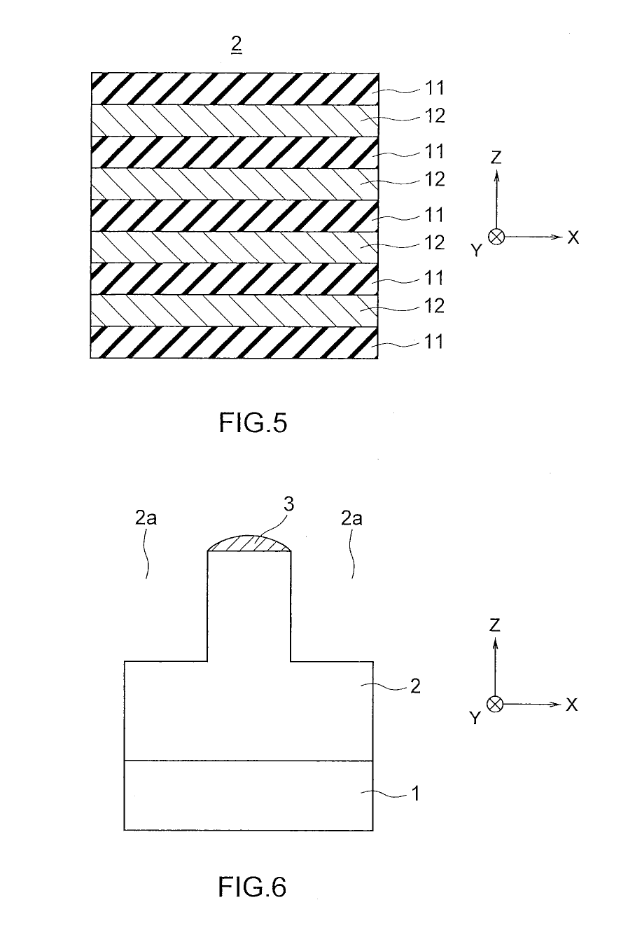

An example of the stack film 2 is shown in FIG. 5. FIG. 5 is a cross-sectional view showing the example of the stack film 2 of the semiconductor device of the first embodiment. The stack film 2 in FIG. 5 includes plural insulating layers 11 and plural electrode layers 12 alternately stacked on the substrate 1. An example of the insulating layers 11 are silicon dioxide films. An example of the electrode layers 12 are polysilicon layers. Each electrode layer 12 functions as a word line or select line for the three dimensional stack memory.

Referring to FIG. 1A again, descriptions are continued of the method of manufacturing the semiconductor device of the first embodiment.

The first hard mask layer 3 in the present embodiment is an amorphous carbon film containing carbon as a main component. The first hard mask layer 3 in the present embodiment may be formed, for example, by chemical vapor deposition (CVD) using a mixed gas of a material gas for the first hard mask layer 3 and a diluent gas for diluting the material gas. Examples of the material gas include propylene and acetylene. Examples of the diluent gas include helium and argon.

In this case, the first hard mask layer 3 contains carbon, hydrogen and oxygen. Carbon and hydrogen in the first hard mask layer 3 are derived from carbon and hydrogen in propylene or acetylene. Examples of the percentages by mass of carbon and hydrogen in the first hard mask layer 3 are about 80% and about 20%, respectively. On the other hand, oxygen in the first hard mask layer 3 is an impurity derived from a residue cleaning gas within a processing chamber. An example of the percentage by mass of oxygen in the first hard mask layer 3 is about 1%.

The carbon film in the present embodiment has advantages as below. First, the carbon film can be removed by ashing. Second, if the carbon film is formed on the workpiece layer having the concave portion, a thick carbon film can be formed on an upper surface of the workpiece layer, and a thin carbon film can be formed in the concave portion of the workpiece layer. These first and second advantages are described later in detail.

Examples of the cover layer 4 include a silicon dioxide film and a silicon nitride film. The cover layer 4 in the present embodiment functions as the hard mask layer and an antireflection coating.

[FIG. 1B]

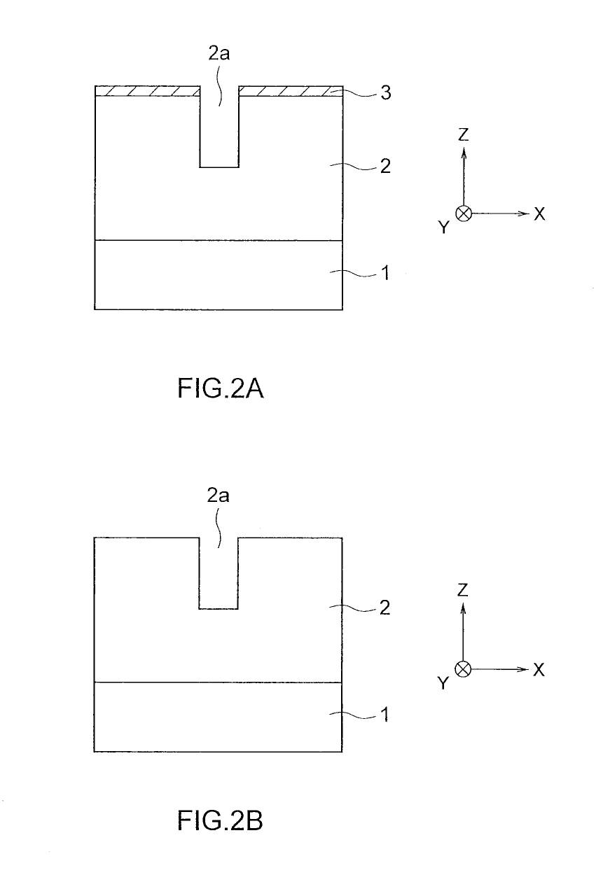

As shown in FIG. 1B, the cover layer 4 and the first hard mask layer 3 are processed by etching using the resist film 5. As shown in FIG. 1B, the resist film 5 and the cover layer 4 are then removed. As a result, a concave portion 3a which penetrates the first hard mask layer 3 is formed.

[FIG. 2A]

As shown in FIG. 2A, a concave portion 2a is formed in the stack film 2 by etching using the first hard mask layer 3. An example of the etching in FIG. 2A is reactive ion etching (RIE), and an example of an etching gas used in this RIE includes a fluorine containing gas. Hereinafter, the etching in FIG. 2A is referred to as first etching.

The first etching in the present embodiment is finished before the first hard mask layer 3 is completely removed by the first etching. The reason for this is described with reference to FIG. 6. FIG. 6 is a cross-sectional view illustrating details of the method of manufacturing the semiconductor device of the first embodiment.

FIG. 6 shows the details of the shape of the first hard mask layer 3 in FIG. 2A. FIG. 6 shows two concave portions 2a for easy understanding of the shape of the first hard mask layer 3. As shown in FIG. 6, a thickness of the first hard mask layer 3 after the first etching is smaller in the vicinity of the concave portions 2a. Therefore, if the first etching is continued until the first hard mask layer 3 is completely removed, the stack film 2 under the first hard mask layer 3 may be damaged by the first etching. For this reason, the first etching in the present embodiment is finished before the first hard mask layer 3 is completely removed by the first etching in order to avoid such a damage.

[FIG. 2B]

Subsequently referring to FIG. 2B, the descriptions are continued of the method of manufacturing the semiconductor device of the first embodiment.

As shown in FIG. 2B, the first hard mask layer 3 is removed by ashing after the first etching. Since the first hard mask layer 3 in the present embodiment is a carbon film, the first hard mask layer 3 can be removed by ashing as described above. According to the present embodiment, the first hard mask layer 3 can be selectively removed without removing the stack film 2. The ashing in FIG. 2B is conducted by using an oxygen radical, for example.

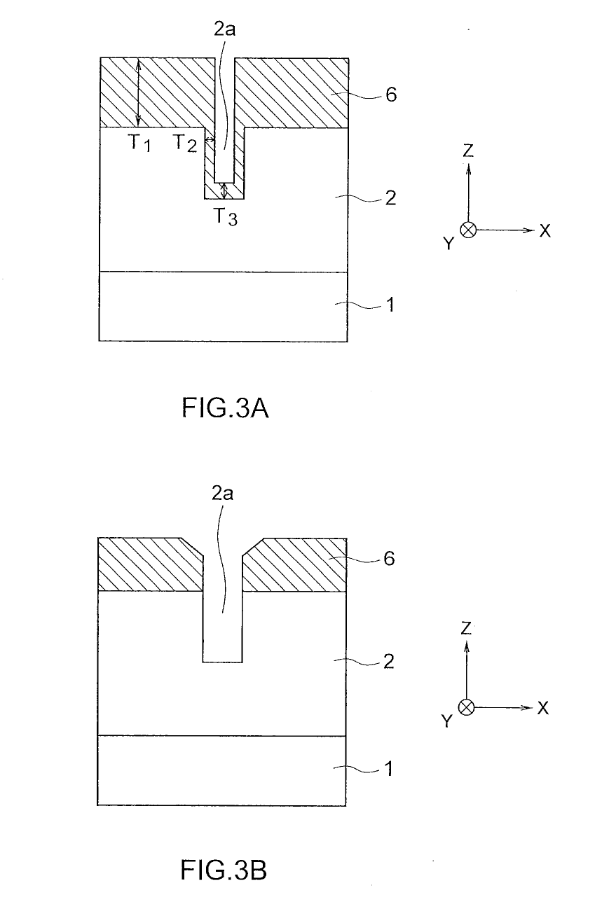

The first hard mask layer 3 may be a film other than the carbon film so long as it can be removed by ashing.

[FIG. 3A]

As shown in FIG. 3A, a second hard mask layer 6 is formed on the stack film 2 in which the concave portion 2a is formed. The second hard mask layer 6 is an example of a second mask layer.

The second hard mask layer 6 in the present embodiment is an amorphous carbon film containing carbon as a main component. The second hard mask layer 6 in the present embodiment is similar to the first hard mask layer 3 in the method of forming, the materials for forming, the composition and the like.

The second hard mask layer 6 in the present embodiment is formed on the upper surface of the stack film 2 and in the concave portion 2a of the stack film 2. A sign T₁ represents a thickness of the second hard mask layer 6 formed on the upper surface of the stack film 2. A sign T₂ represents a thickness of the second hard mask layer 6 formed on a side surface of the concave portion 2a in the stack film 2. A sign T₃ represents a thickness of the second hard mask layer 6 formed on a bottom surface of the concave portion 2a in the stack film 2.

Since the second hard mask layer 6 in the present embodiment is a carbon film, the thick second hard mask layer 6 can be formed on the upper surface of the stack film 2, and the thin second hard mask layer 6 can be formed in the concave portion 2a of the stack film 2, as described above. Therefore, the thickness Tₗ in the present embodiment is larger than the thickness T₂ and the thickness T₃ (T₁>T₂, T₃). Moreover, it is also noted that the thickness T₃ is larger than thickness T₂ (T₃>T₂) in the present embodiment.

[FIG. 3B]

As shown in FIG. 3B, the second hard mask layer 6 in the concave portion 2a of the stack film 2 is removed by etching. An example of the etching in FIG. 3B includes isotropic etching. In this case, the thick second hard mask layer 6 on the upper surface of the stack film 2 and the thin second hard mask layer 6 in the concave portion 2a in the stack film 2 are etched at almost the same etching rate. Therefore, as shown in FIG. 3B, the second hard mask layer 6 is remained on the upper surface of the stack film 2, while all the second hard mask layer 6 in the concave portion 2a in the stack film 2 can be removed.

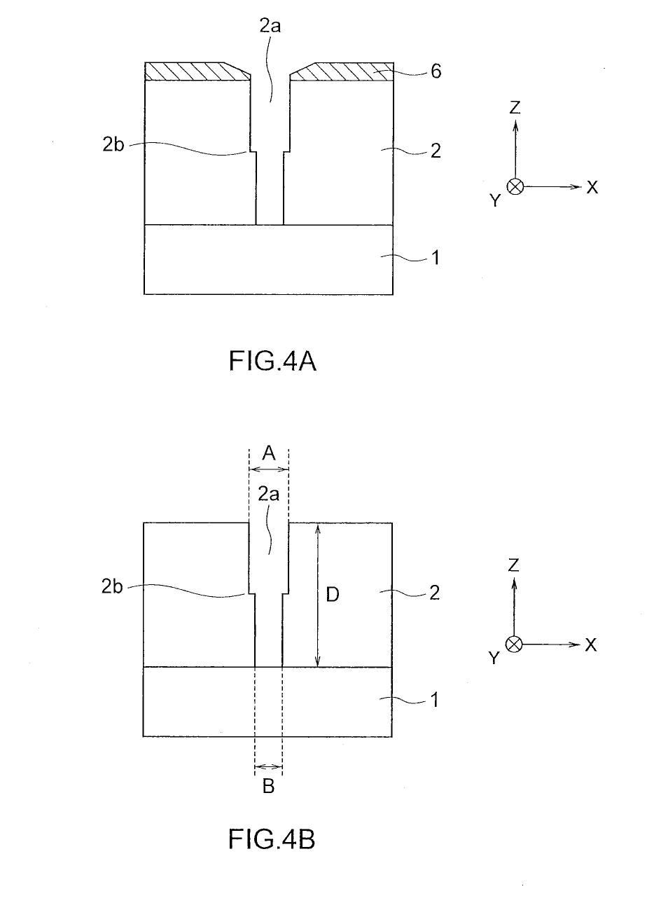

In a case where the thicknesses T₂ and T₃ of the second hard mask layer 6 in the concave portion 2a of the stack film 2 are sufficiently small, the etching in FIG. 3B may be omitted. The reason for this is that if the thicknesses T₂ and T₃ are sufficiently small, the second hard mask layer 6 in the concave portion 2a of the stack film 2 can be removed by etching in FIG. 4A.

[FIG. 4A]

As shown in FIG. 4A, the concave portion 2a of the stack film 2 is processed by etching using the second hard mask layer 6. Specifically, a depth of the concave portion 2a in the stack film 2 is increased to form the concave portion 2a which penetrates the stack film 2. An example of the etching in FIG. 4A is RIE, and an example of the etching gas used in the RIE includes a fluorine containing gas. Hereinafter, the etching in FIG. 4A is referred to as second etching.

The second etching in the present embodiment is finished before the second hard mask layer 6 is completely removed by the second etching. The reason for this is the same as that in the case of the first etching.

[FIG. 4B]

As shown in FIG. 4B, the second hard mask layer 6 is removed by ashing after the second etching. Since the second hard mask layer 6 in the present embodiment is a carbon film, the second hard mask layer 6 can be removed by ashing as described above. According to the present embodiment, the second hard mask layer 6 can be selectively removed without removing the stack film 2. The ashing in FIG. 4B is conducted by using an oxygen radical, for example.

The second hard mask layer 6 may be a film other than the carbon film so long as it can be removed by ashing.

Thereafter, a memory insulator, a channel semiconductor layer, inter layer dielectrics, interconnect layers, plug layers and the like are formed on the substrate 1. In this way, the semiconductor device of the present embodiment is manufactured.

(Details of Method of Manufacturing Semiconductor Device of First Embodiment)

Continuously referring to FIG. 4B, descriptions are given in details of the method of manufacturing the semiconductor device of the first embodiment.

(1) Step Portion 2b

As described above, the concave portion 2a of the stack film 2 in the present embodiment is formed by the first and second etchings. For this reason, the side surface of the concave portion 2a in the stack film 2 may have a step portion 2b after the second etching in some cases. The side surface upper than the step portion 2b is formed by the first etching, and the side surface lower than the step portion 2b is formed by the second etching. However, since a size of the step portion 2b is varied depending on conditions of the first and second etchings and the like, there may be also a case where any step portion 2b is scarcely formed.

A sign “A” represents an opening width of the concave portion 2a in the stack film 2 of FIG. 4B. A sign “B” represents a bottom width of the concave portion 2a in the stack film 2 of FIG. 4B. In the present embodiment, since the side surface of the concave portion 2a in the stack film 2 has the step portion 2b, the bottom width “B” is smaller than the opening width “A”.

(2) Process in FIGS. 3A to 4B

The concave portion 2a of the stack film 2 in the present embodiment is to be used for forming the memory insulator and the channel semiconductor layer of the three dimensional stack memory. For this reason, the concave portion 2a of the stack film 2 in the present embodiment is formed so as to penetrate the stack film 2.

In a case where the concave portion 2a does not penetrate the stack film 2 by the processes in FIGS. 1A to 4B in the present embodiment, the processes in FIGS. 3A to 4B are performed again. In the present embodiment, the processes in FIGS. 3A to 4B are repeatedly performed to be able to form the concave portion 2a which penetrates the stack film 2. In this case, the forming of the second hard mask layer 6 and the second etching are alternately repeated until the concave portion 2a penetrates the stack film 2. If the processes in FIGS. 3A to 4B are repeated N times where N is an integer equal to or more than two, N step portions 2b may be formed on the side surface of the concave portion 2a in the stack film 2.

(3) Method of Manufacturing Semiconductor Device of First Embodiment

As described above, the method of manufacturing the semiconductor device of the present embodiment forms the concave portion 2a in the stack film 2 by the first and second etchings.

Specifically, the method of manufacturing the semiconductor device in the present embodiment includes forming the first hard mask layer 3 on the stack film 2, providing the concave portion 2a in the stack film 2 by the first etching using the first hard mask layer 3, forming the second hard mask layer 6 on the stack film 2 provided with the concave portion 2a, and processing the concave portion 2a of the stack film 2 by the second etching using the second hard mask layer 6.

Therefore, according to the present embodiment, a desired concave portion 2a can be formed in the stack film 2 having a large thickness.

For example, in the case where the first hard mask layer 3 has the small thickness, the first hard mask layer 3 is possibly made to be thinned as shown in FIG. 2A before the concave portion 2a of the stack film 2 is completed by the first etching. In such a case, the second hard mask layer 6 is newly formed on the stack film 2 as shown in FIG. 3A. As a result, the concave portion 2a of the stack film 2 can be processed continuously. Therefore, according to the present embodiment, the concave portion 2a which penetrates the stack film 2 can be finally formed.

A sign “D” represents a depth of the concave portion 2a in the stack film 2 of FIG. 4B. An aspect ratio of the concave portion 2a in the stack film 2 of FIG. 4B is represented by “D/A”. The aspect ratio “D/A” in the present embodiment is set to equal to or larger than one. If the aspect ratio “D/A” becomes larger, it becomes more difficult to form the concave portion 2a in the stack film 2. However, according to the present embodiment, the concave portion 2a can be formed even in such a stack film 2. The concave portion 2a of the stack film 2 in the present embodiment is a hole for embedding therein the memory insulator and the channel semiconductor layer of the three dimensional stack memory.

Although the workpiece layer in the present embodiment is the stack film 2 on the substrate 1, the workpiece layer may be another film on the substrate 1. Furthermore, the workpiece layer of the present embodiment may be the substrate 1 or may be a layer including the substrate 1 and a film on the substrate 1, instead of a film on the substrate 1. An example thereof can include a process of forming a shallow trench isolation (STI). Moreover, an example of the process of forming the concave portion in the workpiece layer which includes the substrate 1 and a film on the substrate 1 is a process of forming the STI in a semiconductor substrate, a gate insulator and a floating gate layer of a NAND memory.

In addition, the present embodiment is applicable to not only a case where the concave portion penetrating the workpiece layer is formed, but also a case where the concave portion having a predetermined depth is formed in the workpiece layer. In this case, the processes in FIGS. 3A to 4B are repeated until the depth of the concave portion of the workpiece layer reaches the predetermined depth.

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods described herein may be made without departing from the spirit of the inventions. The accompanying claims and their equivalents are intended to cover such forms or modifications as would fall within the scope and spirit of the inventions.

1. A method of manufacturing a semiconductor device, comprising:
forming a first mask layer on a workpiece layer;
forming a concave portion in the workpiece layer by first etching using the first mask layer;
forming a second mask layer on the workpiece layer in which the concave portion is formed; and
processing the concave portion of the workpiece layer by second etching using the second mask layer.

2. The method of claim 1, comprising alternately repeating the forming of the second mask layer and the second etching to process the concave portion of the workpiece layer.

3. The method of claim 1, comprising forming the concave portion which penetrates the workpiece layer by the second etching.

4. The method of claim 1, wherein an aspect ratio of an opening width of the concave portion of the workpiece layer and a depth of the concave portion of the workpiece layer is equal to or larger than one after the second etching.

5. The method of claim 1, wherein the first mask layer contains carbon.

6. The method of claim 1, wherein the first mask layer is formed by using a mixed gas of a material gas for the first mask layer and a diluent gas for diluting the material gas.

7. The method of claim 1, comprising removing the first mask layer after the first etching.

8. The method of claim 7, wherein the first mask layer is removed by ashing.

9. The method of claim 1, wherein the second mask layer contains carbon.

10. The method of claim 1, wherein the second mask layer is formed by using a mixed gas of a material gas for the second mask layer and a diluent gas for diluting the material gas.

11. The method of claim 1, wherein the second mask layer is formed on an upper surface of the workpiece layer and in the concave portion of the workpiece layer.

12. The method of claim 11, wherein the second mask layer is formed such that a thickness of the second mask layer on the upper surface of the workpiece layer is larger than a thickness of the second mask layer in the concave portion of the workpiece layer.

13. The method of claim 11, wherein the second mask layer in the concave portion of the workpiece layer is removed between the forming of the second mask layer and the second etching.

14. The method of claim 13, wherein the second mask layer in the concave portion of the workpiece layer is removed by isotropic etching.

15. The method of claim 1, further comprising removing the second mask layer after the second etching.

16. The method of claim 15, wherein the second mask layer is removed by ashing.

17. The method of claim 1, wherein a side surface of the concave portion of the workpiece layer comprises a step portion after the second etching.

18. The method of claim 1, wherein a bottom width of the concave portion of the workpiece layer is smaller than an opening width of the concave portion of the workpiece layer after the second etching.

19. The method of claim 1, wherein the workpiece layer comprises plural insulating layers and plural electrode layers which are alternately stacked.

20. The method of claim 1, wherein the workpiece layer comprises a substrate or/and a film formed on the substrate.
